(19) United States
(12) Patent Application Publication
(10) Pub. No.: US 2011/0032976 A1
(43) Pub. Date: Feb. 10, 2011

(54) Start-up Procedure Method and Timing Recovery for Receiver of Communication System

(76) Inventors: Wen-Sheng Hou, Hsinchu County (TW); Guan-Henry Lin, Taichung (TW); Li-Hua Weng, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/822,156

(22) Filed: Jun. 23, 2010

(30) Foreign Application Priority Data
Aug. 4, 2009 (TW) 098126181

(51) Int. Cl. H04B 3/46; H04B 1/10; H03H 7/30

(52) U.S. Cl. 375/226; 375/346; 375/229

(57) ABSTRACT

A method for starting up a receiver of a communication system includes training an interference canceller of the receiver, keeping the interference canceller in a tracking state after the interference canceller converges, and starting to train a timing recovery device of the receiver.

### BACKGROUND OF THE INVENTION

1. Field of the Invention

The present invention relates to a method for starting up a receiver of a communication system and timing recovery device, and more particularly, to a method and timing recovery device capable of enhancing convergence ability and reducing convergence time.

2. Description of the Prior Art

In a gigabit Ethernet system, a receiver adopts a decision directed method to gradually converge parameters of functional blocks including automatic gain control (AGC), near end cross talk (NEXT) canceller, echo canceller, timing recovery device, and equalizer. However, in the start-up procedure, there is no available training sequence but severe echo interference, such that the convergence time cannot be effectively reduced. Additionally, interactions among the functional blocks can easily result in start-up errors, i.e. error propagation, and fail to obtain appropriate parameters. For example, an operation result of the timing recovery device changes sampling phase of the digital-to-analog convertor (DAC), and hence changes sampling phases of both the NEXT canceller and the echo canceller. Therefore, an effective start-up procedure is needed to ensure convergence of each functional block.

Besides the convergence issue, there is a timing recovery issue. In the gigabit Ethernet system, one of two peer transceivers having established communication connection is operated in a master mode, named “master device”, while the other is operated in a slave mode, named “slave device”. A transmitter of the master device utilizes a free running clock to transmit signals to the slave device. When a receiver of the slave device receives the signals, the slave device executes clock recovery operations, to generate a recovered clock identical to the free running clock. Next, transmitter and receiver of the slave device transmit and sample signals respectively based on the recovered clock. When the receiver of the master device receives signals transmitted from the slave device using the recovered clock, the receiver of the master device performs synchronization, to optimize the sampling phase. In short, clock used by the transmitter of the master device is not recovered from signals received by the receiver of the master device, whereas clock used by the transmitter of the slave device must be recovered from signals received by the receiver of the slave device. In such a situation, since operations of clock recovery are different between the master device and the slave device, resulting in increased complexity of the start-up procedure.

### SUMMARY OF THE INVENTION

It is therefore an objective of the present invention to provide a method for starting up a receiver of a communication system and a timing recovery device.

The present invention discloses a method for starting up a receiver of a communication system, which comprising training an interference canceller of the receiver, keeping the interference canceller in a tracking state after the interference canceller converges, and starting to train a timing recovery device of the receiver.

The present invention further discloses a timing recovery device for a communication system, which comprises a timing error detection module for detecting timing errors in received signals of the receiver to generate a detection result, a loop filter module for filtering noises in the detection result to generate a filtered result, a numerical controlled oscillator (NCO) module to generate a oscillating signal to an analog-to-digital convertor (ADC) based on the filtered result, and a start-up control module to adjust the oscillating signal generated by the NCO module while the receiver is in a start-up procedure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a receiver installed in a transceiver of the gigabit Ethernet system.

FIG. 2 is a flowchart of a start-up process according to an embodiment of the present invention.

FIG. 3 is a flowchart of a control process controlling the operation of timing recovery of a timing recovery device in the start-up procedure of the present invention.

FIG. 4 is a schematic diagram of an embodiment of the start-up control module of the present invention.

### DETAILED DESCRIPTION

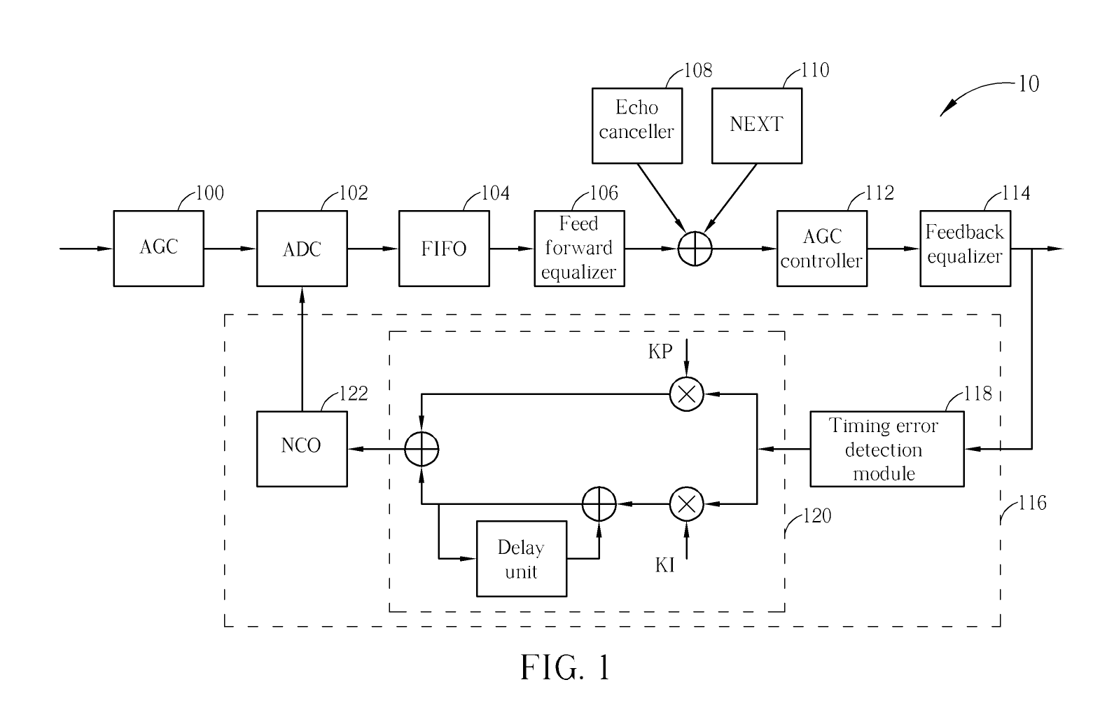

In order to improve the prior art start-up procedure of the gigabit Ethernet system, the present invention enhances convergence efficiency through a specific training order. First, please refer to FIG. 1. FIG. 1 is a schematic diagram of a receiver 10. The receiver 10 is installed in a transceiver device of the gigabit Ethernet system, for receiving signals from a twisted pair, and comprises an analog automatic gain control (AGC) 100, an analog-to-digital converter (ADC) 102, a first-in first-out (FIFO) memory 104, a feed forward equalizer 106, an echo canceller 108, a near end cross talk (NEXT) canceller 110, an AGC controller 112, a feedback equalizer 114 and a timing recovery device 116. Detailed operations of the receiver 10 is well known for those skilled in the art, and are abriged herein. The analog ADC 100 adjusts amplitude of received signals to conform an operational region of the ADC 102. The ADC 102 converts analog signals to digital signals based on oscillating signals outputted by the timing recovery device 116, and outputs the digital signals to the FIFO memory 104. The feed forward equalizer 106 is utilized to cancel a pre-cursor portion of inter-symbol interference, while the feedback equalizer 114 is utilized to cancel a post-cursor portion of inter-symbol interference. The combination of the feed forward equalizer 106 and the feedback equalizer 114 fulfills complete function of equalization. The timing recovery device 116 recovers frequency and phase of clock signals, and comprises a timing error detection module 118, a loop filter module 120, and a numerical control oscillator (NCO) 122. The timing error detection module 118 detects timing errors of received signals, the loop filter 120 filters out noises, and the NCO 122 generates oscillating signals accordingly, such tat the ADC 102 performs analog to digital convertion with accurate sampling phases.

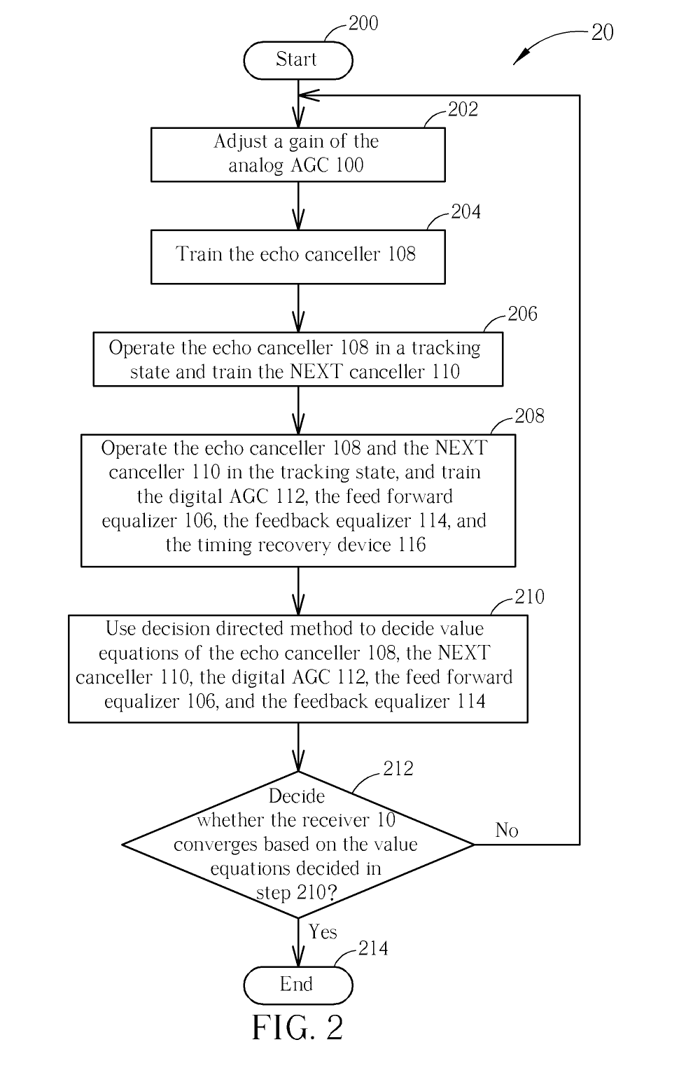

Please refer to FIG. 2. FIG. 2 is a flowchart of a start-up process 20 according to an embodiment of the present invention. The start-up process 20 is utilized to start up the receiver 10, and includes the following steps:

Step 200: Start.

Step 202: Adjust a gain of the analog AGC 100.

Step 204: Train the echo canceller 108.

Step 206: Operate the echo canceller 108 in a tracking state and train the NEXT canceller 110.

Step 208: Operate the echo canceller 108 and the NEXT canceller 110 in the tracking state, and train the digital AGC 112, the feed forward equalizer 106, the feedback equalizer 114, and the timing recovery device 116.

Step 210: Use decision directed method to decide value equations of the echo canceller 108, the NEXT canceller 110, the digital AGC 112, the feed forward equalizer 106, and the feedback equalizer 114.

Step 212: Decide whether the receiver 10 converges based on the value equations decided in step 210. If true, proceed to step 214; else, back to step 202.

Step 214: End.

According to the start-up process 20, the present invention first adjusts the gain of the analog AGC 100, such that the ADC 102 efficiently samples the received signals. After that, the present invention continues to train interference cancellers, which includes steps of training the echo canceller 108 first, keeping the echo canceller in the tracking state after the echo canceller 108 converges, and training the NEXT canceller 110. In detail, echo interference is induced by signals transmitted from a transceiver device related to the receiver 10, while NEXT interference is induced by signals of other twisted pairs. Therefore, an amount of energy decay of signals from another transceiver device in a long cable situation is greater than that in a short cable situation, while energy of echo interference is the same under the both situations. In other words, a noise-to-signal ratio caused by echo interference in the long cable situation is smaller than that in the short cable communication case. Therefore, the present invention uses the echo canceller 108 to eliminate echo interference in the first place. The value equation used to train parameters of the echo canceller 108 can adopt minimum output energy (MOE) with echo cancelled, or be realized with least mean square (LMS) algorithm.

In addition, due to deficiency of information about delay time between the transmitted signals and the receiver 10 in the training process of the echo canceller 108, longer taps can be used in the beginning. After the echo canceller 108 converges, information about the delay time can be derived from the maximum among absolute values of the taps, and then reduce the tap length to enhance the tracking and convergence abilities of the echo canceller 108.

Next, after the echo canceller 108 and the NEXT canceller 110 converge, the present invention keeps both of them in the tracking state, and trains the digital AGC 112, the feed forward equalizer 106, the feedback equalizer 114, and the timing recovery device 116. Preferably, a gain of the digital AGC 112 can be decided with a blind decision method at the beginning of the training process, to ensure output values of the digital AGC 112 being large enough to facilitate operations of the decision directed algorithm. After convergence of the blind decision method, the decision directed training method is soon adopted, so as to enhance convergence.

The equalizers, including the feed forward equalizer 106 and the feedback equalizer 114, are trained with the decision directed method. Training of the timing recovery device 116 is much complex and would be detailed hereafter. After all the functional blocks complete trainings, in order to minimize convergence errors of the whole system, the present invention uses the decision directed method to decide the value equations of tracking algorithm of the echo canceller 108, the NEXT canceller 110, the digital AGC 112, the feed forward equalizer 106, and the feedback equalizer 114. If the system cannot converge, the training process will be restarted.

Since operational results of the timing recovery device 118 change sampling phases of the ADC converter 10, and further change sampling phases of the echo canceller 108 and the NEXT canceller 110, the present invention first performs trainings of the echo canceller 108 and the NEXT canceller 110, and then goes to training of the timing recovery device 118.

Moreover, though the echo canceller 108 and the NEXT canceller 110 are kept in the tracking state during the training of the timing recovery device 118, the timing recovery device 118 is in an acquisition stage, in which phase shifts so rapidly that the echo canceller 108 and the NEXT canceller 110 cannot track and catch up changes of sampling phases of the analog ADC 102, and thus, echo and NEXT cannot be eliminated or system cannot converge. To improve the above situation, the present invention decides whether to suspend timing recovery operations of the timing recovery device 118 according to the status of phase shifts when performing training of the timing recovery device 118, to ensure the echo canceller 108 and the NEXT canceller 110 can track and catch up changes of sampling phases.

On the other hand, since the receiver 10 can be operated in master mode or slave mode, training of the timing recovery device 118 differs in these modes.

Concerning the master-mode receiver 10, the timing recovery device 118 is only used to lock the phase of received signals, and does not provide clock signal for the transmitter, and hence the loop filter module 120 can be simplified as a one-order loop filter, i.e. K1=0. Then, as stated above, in order to ensure the echo canceller 108 and the NEXT canceller 110 can track and catch up changes of sampling phases of the analog ADC 102, when an accumulated phase shift exceeds a predefined degree (ex. a threshold) in a predefined period of time, the present invention suspends the operation of timing recovery of the timing recovery device 118 for a predefined period of time, that is, to make the output of the loop filter module 120 zero, representing no timing error, or to replace the output of the loop filter module 120 with zero. Under such circumstance, since the loop filter module 120 is a one-order loop filter, when the input of the loop filter module 120 is zero, the NCO module 122 keeps outputting the result of the preceding cycle, meaning that the sampling phase of the ADC 102 will be kept. As a result, the echo canceller 108 and the NEXT canceller 110 have enough time to track phase shift to maintain convergence. Therefore, by adequately keeping the phase unchanged (i.e. pausing the operation of timing recovery of the timing recovery device 118), the receiver 10 can lock the phase of received signals, and more importantly, the echo canceller 108 and the NEXT canceller 110 can keep tracking abilities.

Furthermore, when the receiver 10 is in the slave mode, one of the four twisted pairs recovers the clock signal needed by all transmitters. Hence, two different situations are provided. In the first situation, the receiver 10 recovers the clock signal needed by all the transmitters from the received signals; in other words, the transmitters corresponding to the receiver 10 perform digital-to-analog conversion with the clock signal recovered by the timing recovery device 118. Therefore, the echo canceller 108 and the NEXT canceller 110 do not change parameters of the tap length if the sampling phase of the ADC 102 changes. That is to say, for the slave-mode operation which recovers the clock signal for all the transmitters, the receiver 10 can neglect the influence of the sampling phase shift of the ADC 102 on the tracking abilities of the echo canceller 108 and the NEXT canceller 110.

As to the second situation, the receiver 10 does not need to provide clock signals to the transmitters; in other words, the receiver 10 only needs to adjust phases, and the loop filter module 120 is simplified as a one-order loop filter. Under such circumstance, when the sampling phase of the ADC 102 changes, like the case of the master mode, the sampling phases of the echo canceller 108 and the NEXT canceller 110 are affected, which further influence convergence. The solution is to the same to the master mode; that is, when an accumulated phase shift of the ADC 102 exceeds a threshold in a predefined period of time, the operation of timing recovery of the timing recovery device 118 is suspended for a predefined period of time, waiting for the convergence of the echo canceller 108 and the NEXT canceller 110.

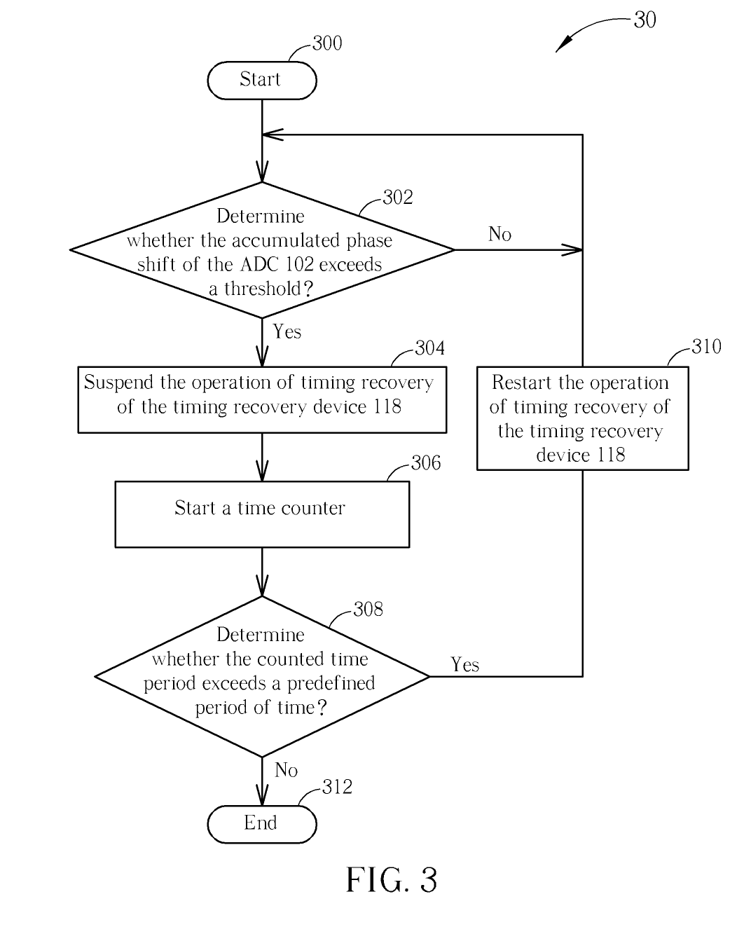

Therefore, either in the master mode or the slave mode, if the receiver 10 does not need to provide clock signal for the transmitters, the present invention decides whether to suspend the operation of timing recovery of the timing recovery device 118 on the basis of phase shifts, to avoid the situation that the echo canceller 108 and the NEXT canceller 110 fail to track the sampling phase. That is, when the accumulated phase shift of the ADC 102 exceeds a threshold in a predefined period of time, the present invention suspends the operation of timing recovery of the timing recovery device 118 for a predefined period of time, waiting for the convergence of the echo canceller 108 and the NEXT canceller 110. The operation can be summarized into a control process 30, used for controlling the operation of timing recovery of the timing recovery device 118 in the start-up procedure, as shown in FIG. 3. The timing recovery control process 30 includes the following steps:

Step 300: Start.

Step 302: Determine whether the accumulated phase shift of the ADC 102 exceeds a threshold. If true, proceed to step 304; else, keep on the determination.

Step 304: Suspend the operation of timing recovery of the timing recovery device 118.

Step 306: Start a time counter.

Step 308: Determine whether the counted time period exceeds a predefined period of time. If true, proceed to step 310; else, perform step 312.

Step 310: Restart the operation of timing recovery of the timing recovery device 118.

Step 312: End.

Note that, an additional start-up control module can be added to the timing recovery device 118 to realize the timing recovery control process 30, in order to calculate accumulated phase shifts while the receiver 10 is performed in the start-up procedure, and adjust the oscillating signals generated by the NCO 122 accordingly. Needless to say, ways to realize the start-up procedure are not limited to specific rules, software, and hardware, as long as the above-stated operations can be achieved. In addition, the timing recovery control process 30 aims at receivers that do not need to provide recovered clock to transmitters, which implies some of the receivers in slave mode may need to execute the timing recovery control process 30 while the others do not, and the configuration of the start-up control module must be changed accordingly.

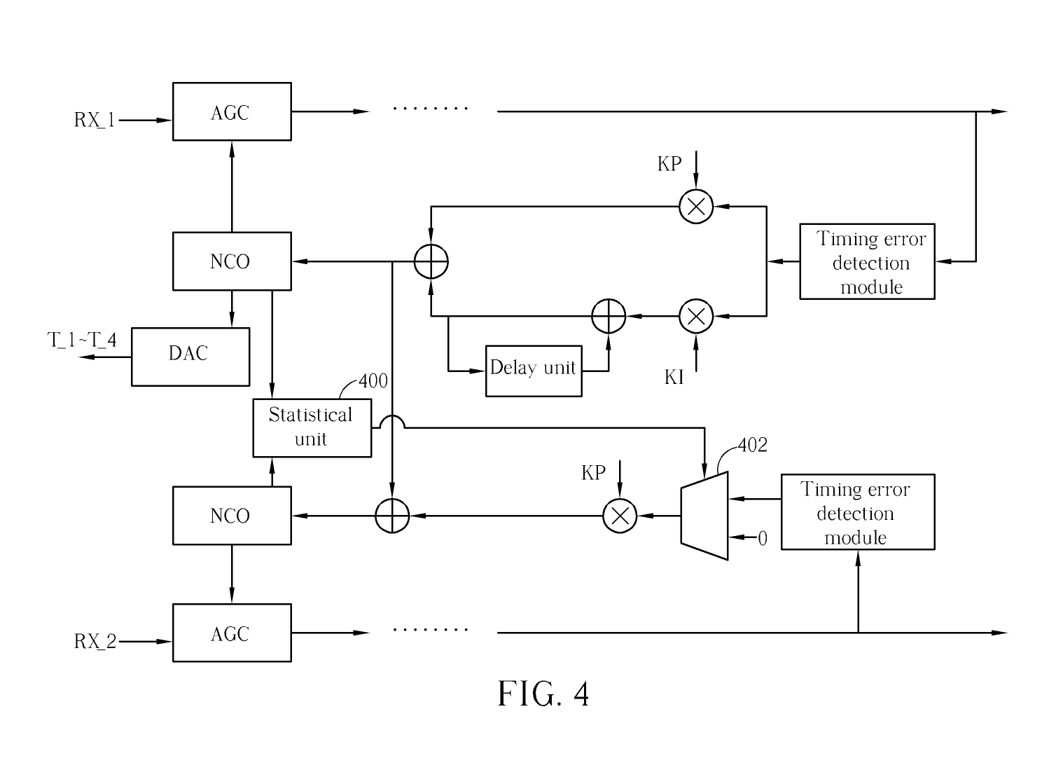

For example, FIG. 4 is a schematic diagram of an embodiment of the start-up control module. In FIG. 4, RX_1 represents a twisted pair, which needs to recover clock signal for all the transmitters T1-T4. Among the other three twisted pairs, only one is shown, and marked as RX_2. The start-up control module consists of a statistical unit 400 and a selection unit 402. The statistical unit 400 calculates the phase shift of the ADC. When a statistical result indicates that the phase shift exceeds a predefined degree in a predefined period of time, the statistical unit 400 controls the selection unit 402 to replace the output of the timing recovery module with zero to keep the phase unchanged.

Note that, FIG. 4 depicts a possible embodiment to realize the timing recovery process 30. In fact, besides setting the output of the timing error detection module by replacement, the function can also be achieved by controlling the operation of the timing error detection module, and is not limited to it.

In the prior art, the operation result of the timing recovery device changes the sampling phase of ADC, and hence changes the sampling phases of the NEXT canceller and the echo canceller, making the echo canceller and the NEXT canceller unable to converge in a short period, and resulting in convergence failure. In comparison, the present invention first adjusts the gain of the analog ADC, and then performs training of the interference (echo and NEXT) cancellers; after the interference cancellers converge, the present invention keeps them in the tracking state, and trains the digital AGC controller, the equalizers, and the timing recovery device; finally, the present invention uses the decision-directed method to decide the value equations, to reduce the convergence error. In the training of the timing recovery device, if the receiver does not need to provide clock signal for the transmitters, the present invention calculates the phase shift of the ADC in a predefined period of time. When the accumulated phase shift exceeds a threshold, the present invention suspends the operation of timing recovery of the timing recovery device, to keep the phase unchanged and enable the interference cancellers to track the phase shift, so as to keep tracking ability, and avoid failure in convergence.

In conclusion, the present invention enhances the efficiency of convergence through an adequate training order and ensures the tracking ability of the interference cancellers by timely keeping the phase unchanged. Therefore, the start-up procedure of the present invention effectively raises the convergent ability while reducing the time for convergence; likewise, the start-up procedures for the master mode and the slave mode in the present invention are almost the same, thereby reducing complexity.

Those skilled in the art will readily observe that numerous modifications and alterations of the device and method may be made while retaining the teachings of the invention.

What is claimed is:

1. A method for starting up a receiver of a communication system comprising:
training an interference canceller of the receiver;
keeping the interference canceller in a tracking state after the interference canceller converges; and
starting to train a timing recovery device of the receiver.

2. The method of claim 1, wherein the interference canceller is an echo canceller.

3. The method of claim 1, wherein the interference canceller is a near end cross talk (NEXT) canceller.

4. The method of claim 1, further comprising controlling a timing-recovery operation of the timing recovery device based on a phase shift caused by training of the timing recovery device.

5. The method of claim 4, wherein the step of controlling the timing-recovery operation of the timing recovery device based upon the phase shift caused by training of the timing recovery device comprises stopping the timing-recovery operation of the timing recovery device, to make the interference canceller operated in the tracking state to track the phase shift caused by the timing recovery device, when the phase shift caused by training of the timing recovery device exceeds a predefined degree during a predefined period of time.

6. The method of claim 5, further comprising restarting the timing-recovery operation of the timing recovery device at a time after the timing-recovery operation of the timing recovery device is stopped.

7. The method of claim 4, wherein the receiver is operated in a master mode.

8. The method of claim 4, wherein the receiver is operated in a slave mode, and timings recovered by the timing recovery device are only used for the receiver to process received signals.

9. A timing recovery device for a communication system comprising:
a timing error detection module for detecting timing errors of signals received by the receiver, to generate a detection result;
a loop filter module for filtering out noises in the detection result, to generate a filtered result;
a numerical controlled oscillator (NCO) module for generating an oscillating signal to an analog-to-digital converter based on the filtered result; and
a start-up control module for adjusting the oscillating signal generated by the NCO module when the receiver is operated in a start-up procedure.

10. The timing recovery device of claim 9, wherein the start-up control module comprises:
a statistical unit for calculating a phase shift of the oscillating signal, to generate a statistic result, when the receiver is operated in a start-up procedure; and
a selection unit for replacing the detection result generated by the timing error detection module with a detection result of zero timing error, to keep the oscillating signal unchanged, when the statistic result indicates that the phase shift of the oscillating signal exceeds a predefined degree during a predefined period of time.

11. The timing recovery device of claim 10, wherein the selection unit is further utilized for retransmitting the detection result generated by the timing error detection module to the loop filter module at a time after the detection result generated by the timing error detection module is replaced with the detection result of zero timing error.

12. The timing recovery device of claim 9, wherein the receiver is operated in a master mode.

13. The timing recovery device of claim 9, wherein the receiver is operated in a slave mode, and the oscillating signal generated by the NCO module is only used for the analog-to-digital converter to process received signals.
